(19) United States
(12) Patent Application Publication
(10) Pub. No.: US 2026/0360440 A1
(43) Pub. Date: Nov. 12, 2026

(54) EXTRACTION METHOD OF PHYSICALLY UNCLONABLE FUNCTION IN MEMORY DEVICE AND MEMORY DEVICE

(71) Applicant: MACRONIX International Co., Ltd., Hsinchu (TW)

(72) Inventors: You-Liang Chou, Taichung City (TW); Wen-Che Tsai, Hualien City (TW)

(73) Assignee: MACRONIX International Co., Ltd., Hsinchu (TW)

(21) Appl. No.: 19/200,682

(22) Filed: May 7, 2025

(51) Int. Cl. G11C 16/22; G11C 16/08; G11C 16/24; G11C 16/26

(52) U.S. Cl. CPC G11C 16/22; G11C 16/08; G11C 16/24; G11C 16/26

(57) ABSTRACT

Disclosed are an extraction method of a physically unclonable function (PUF) and a memory device. The memory device may be a three-dimensional NAND flash memory with high capacity and high performance. The extraction method includes: performing a weak PUF processing operation on a first memory sub-block; and, performing a strong PUF read operation to the pages in the first memory sub-block to extract a strong PUF data. The step for extracting the strong PUF data includes: applying a first voltage to first word lines corresponding to a page to be selected of the first memory sub-block and applying a second voltage to word lines other than the first word lines at the same time, the first voltage is different from the second voltage; and, sensing currents of bit lines to be selected to extract the strong PUF data.

### BACKGROUND

### Technical Field

The present disclosure relates to a technology applied to memory devices (e.g., NAND flash memory), and particularly relates to an extraction method of a physically unclonable function and a memory device.

### Description of Related Art

High-capacity and high-performance integrated circuit memories incorporating three-dimensional NAND flash memory (3D NAND flash memory) are continuously under development. It is expected that the utilization of three-dimensional stacking technology and triple-level cells (TLC) may help to reduce dimensions of memory cells while increasing data storage density. Conversely, physically unclonable function (PUF) technology, based on manufacturing process variations, enables components manufactured through semiconductor manufacturing processes to generate highly random and unpredictable data, which may be utilized for identity verification, device key generation, communication security, and other purposes, possessing distinctive uniqueness.

The corresponding technologies utilizing integrated circuit memory to generate PUFs are progressively evolving. These PUF extraction techniques typically require substantial additional circuitry to compare data values within the integrated circuit memory in order to obtain the corresponding PUF. Moreover, the PUF data throughput of these extraction techniques is not substantial. Therefore, one of the issues to be further explored is how to generate a significant quantity of PUF data based on integrated circuit memory.

### SUMMARY

The present disclosure provides an extraction method of a physically unclonable function and a memory device, which may utilize the existing hardware structure of the memory device to perform multi-page read on the same memory sub-block, thereby extracting a large quantity of strong PUF data.

The present disclosure provides an extraction method of a physically unclonable function (PUF). The memory device comprises a memory block, wherein the memory block comprises a plurality of memory sub-blocks, each of the plurality of the memory sub-blocks comprises a plurality of memory cells, the plurality of the memory cells are divided into a plurality of pages, and the plurality of pages correspond to a plurality of word lines. The extraction method includes: performing a weak PUF processing operation on a first memory sub-block among the plurality of the memory sub-blocks, wherein each of the plurality of the memory cells in the first memory sub-block has a PUF data thereof after the weak PUF processing operation is performed; selecting at least one page to be selected from the plurality of the pages in the first memory sub-block; and, performing a strong PUF read operation on the plurality of the pages in the first memory sub-block to extract strong PUF data, wherein the step of performing the strong PUF read operation on the plurality of the pages in the first memory sub-block includes: applying a first voltage to a first word line corresponding to the at least one page to be selected, while applying a second voltage to a second word line other than the first word line, wherein the second word line is the plurality of the word lines other than the first word line, and the first voltage is different from the second voltage; and, after applying the first voltage to the first word line and applying the second voltage to the word lines other than the first word line, sensing currents of a plurality of bit lines to be selected to extract the strong PUF data, wherein the plurality of the bit lines to be selected is selected from a plurality of bit lines of the first memory sub-block.

The present disclosure provides a memory device. This memory device includes a memory array, a memory controller, a bit line decoder, and a word line decoder. The memory array includes a memory block, wherein the memory block includes a plurality of memory sub-blocks, each of the plurality of the memory sub-blocks includes a plurality of the memory cells, the plurality of the memory cells are divided into a plurality of pages, and the plurality of the pages correspond to a plurality of word lines. The memory controller is configured to: perform a weak PUF processing operation on a first memory sub-block among the plurality of the memory sub-blocks, wherein each of the plurality of the memory cells in the first memory sub-block has a PUF data thereof after the weak PUF processing operation is performed; select at least one page to be selected from the plurality of the pages in the first memory sub-block; and, through the word line decoder and the bit line decoder, perform a strong PUF read operation on the plurality of the pages in the first memory sub-block to extract strong PUF data, wherein the memory controller controls the word line decoder to apply a first voltage to a first word line corresponding to the at least one page to be selected, while applying a second voltage to a second word line other than the first word line, wherein the second word line is the plurality of the word lines other than the first word line, and the first voltage is different from the second voltage.

Based on the foregoing, the embodiments of the present disclosure primarily utilize the existing hardware structure of memory devices (such as bit line decoders, word line decoders, sub-block selection circuits, etc.) and some additional functionalities (such as corresponding functions added to the memory controller and multi-page read operations) to achieve PUF data extraction. In the aforementioned multi-page read operation of the present embodiment, one or more pages are selected, and some of bit lines are selected from BL1 to BLN as a plurality of bit lines to be selected, thereby enhancing the randomness of PUF data through mathematical permutations and combinations. Furthermore, by utilizing sense amplifiers in the bit line decoder to sense currents of the plurality of the bit lines to be selected, a substantial quantity of strong PUF data may be extracted in a single read operation, increasing PUF data throughput without requiring additional comparison circuits.

### BRIEF DESCRIPTION OF THE DRAWINGS

FIG. 1 is a structural diagram illustrating a memory device according to an embodiment of the present disclosure.

FIG. 2 is a diagram illustrating each page in the memory sub-block Sub_0 of FIG. 1.

FIG. 3 is a diagram illustrating the selection of corresponding pages by providing different read voltages to word lines of different pages in a strong PUF read operation according to an embodiment of the present disclosure.

FIG. 4 is a flowchart of an extraction method of a physically unclonable function in a memory device according to an embodiment of the present disclosure.

FIG. 5 is a diagram illustrating various signals in an example of the extraction method of FIG. 4.

FIG. 6 is a natural probability distribution diagram of the number of memory cells with high threshold voltage on specific memory cell strings in pages P1 to P96 in the memory sub-block Sub_0.

FIG. 7 is a diagram illustrating the current threshold range between sensing currents IthL and IthH in FIG. 6.

### DESCRIPTION OF THE EMBODIMENTS

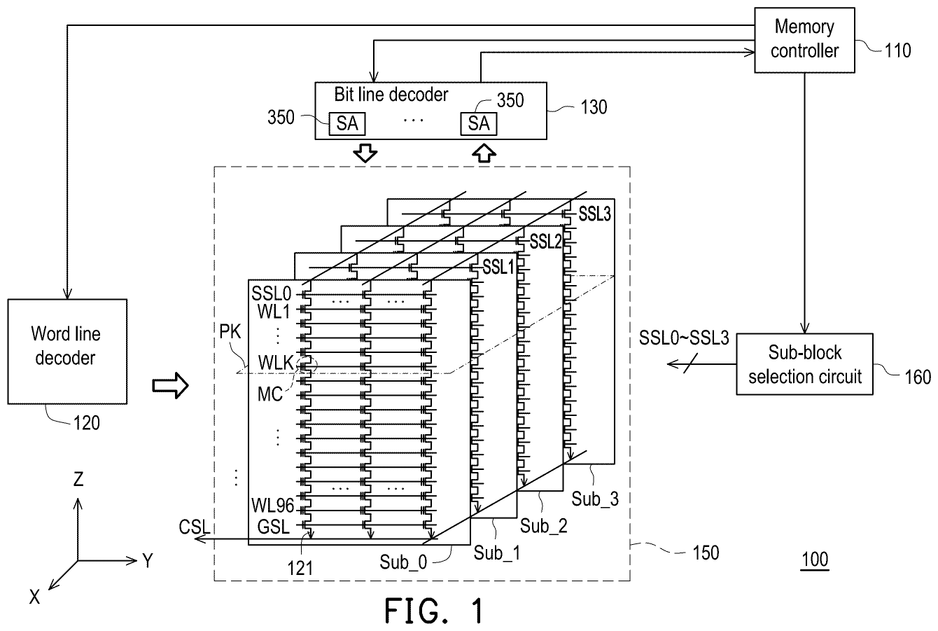

FIG. 1 is a structural diagram of a memory device 100 according to an embodiment of the present disclosure. The memory device 100 may be a 3D NAND flash memory with high capacity and high performance. Referring to FIG. 1, the memory device 100 includes a memory array, a memory controller 110, a bit line decoder 130, and a word line decoder 120. The memory device 100 may also include a sub-block selection circuit 160. The memory array includes at least one memory block 150.

The memory block 150 may be divided into multiple memory sub-blocks (e.g., memory sub-blocks Sub_0 to Sub_3) based on each YZ plane in FIG. 1. Each memory sub-block Sub_0 to Sub_3 may be selected through string select lines (e.g., string select lines SSL0 to SSL3).

Each memory sub-block Sub_0 to Sub_3 includes multiple memory cell strings (e.g., memory cell string 121). Each memory cell string (memory cell string 121) includes multiple memory cells (e.g., a memory cell MC) connected vertically in series along the Z direction. In the same memory sub-block, each memory cell string corresponds to different bit lines (e.g., bit lines BL1 to BLN). The memory cells (e. g., the memory cell MC) in the memory block 150 are configured in three dimensions, for example, XYZ coordinate system. Taking the memory cell MC in FIG. 1 as an example, the memory cell MC is coupled to the corresponding word line WLK and bit line BL1. The multiple memory cells in the memory cell string 121 in FIG. 1 belong to different pages (e. g., page PK).

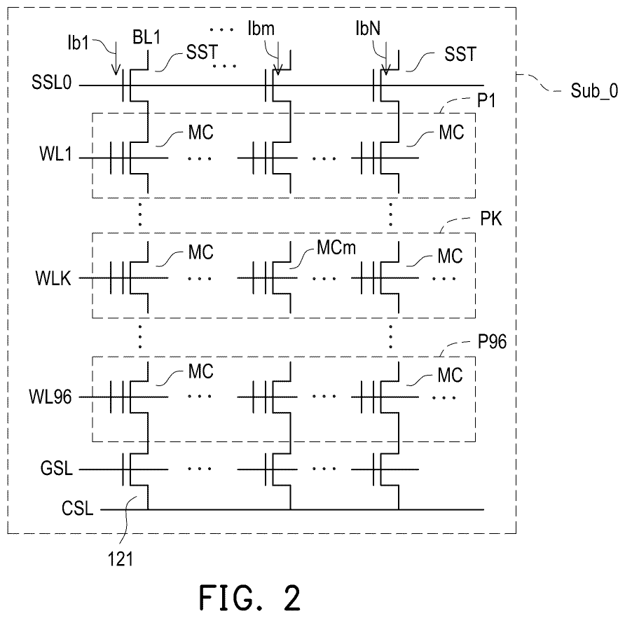

FIG. 2 is a diagram illustrating various pages (e. g., pages P1 to P96) in the memory sub-block Sub_0 of FIG. 1. Referring to both FIG. 1 and FIG. 2, each memory sub-block Sub_0 to Sub_3 includes multiple memory cells (e.g., memory cell MC). These memory cells MC are divided into multiple pages (e. g., pages P1 to P96 in FIG. 2). Pages P1 to P96 correspond to multiple word lines WL1 to WL96 respectively.

Taking the memory sub-block Sub_0 in FIG. 2 as an example, the word lines (e.g., word lines WL1 to WL96) formed through conductive layers or word line layers and the multiple memory cells coupled with them are divided into multiple pages (e.g., pages P1 to P96 in FIG. 2). Memory cells on the same layer (same page) may be coupled to the same word line and receive the corresponding word line voltage. Memory cells on different layers (different pages) are coupled to different word lines (e.g., word lines WL1 and WL96) and receive different word line voltages. In other words, a page in the memory sub-block Sub_0 consists of memory cells in these memory cell strings that are connected to one (for example, one of the word lines WL1 to WL96) of the corresponding multiple word lines. Each page may be connected to the corresponding contact in the driving circuit through one of the word lines WL1 to WL96 coupled to this page, for example, connected to a scan driver. Each line has a corresponding voltage driver, and these voltage drivers may be controlled by the memory controller 110 or corresponding hardware.

Referring to both FIG. 1 and FIG. 2, the memory cell string 121 includes multiple memory cells, a string select transistor SST coupled to the string select line SSL0, and a ground select transistor GST coupled to the ground select line GSL. The memory cell string 121 may be connected to one or more drivers, such as a data driver, through the bit line BL1. The memory cell MC in the memory cell string 121 is connected to the common source line CSL through the ground select transistor GST. The string select lines SSL0 to SSL3 may be conductive wires or conductive layers formed on the top of each page (or word line layer). The memory block 150 may include multiple string select lines SSL0 to SSL3 provided on the page located at the top. The ground select line GSL may be a conductive wire or conductive layer formed on the bottom of each page (or word line layer). The common source line CSL may be a conductive layer or multiple conductive wires formed below the ground select line GSL and on the substrate in this memory device 100. Several dummy lines or corresponding layers (not shown) may also be arranged between the string select lines SSL0 to SSL3 and the topmost page, or between the ground select line GSL and the bottommost page.

The memory cells in the memory block 150 may be single-level memory cells (SLC) or multi-level memory cells. “Multi-level memory cells” are, for example, one of multi-level cells (MLC), triple-level cells (TLC), and quad-level cells (QLC). The memory cells in the memory device and the memory block 150 of this embodiment are exemplified as single-level memory cells (SLC).

The embodiments of the present disclosure primarily utilize the existing hardware structure of the memory device 100 (such as bit line decoder 130 and a sense amplifier SA 350 thereof, word line decoder 120, sub-block selection circuit 160, etc.) and some additional functionalities (such as corresponding functions added to the memory controller 110 and strong PUF read operations) to implement the extraction of PUF data. In this embodiment, during the aforementioned strong PUF read operation, by selecting one or more pages from all pages (such as pages P1 to P96) in the memory block, and selecting some bit lines from bit lines BL1 to BLN as multiple bit lines to be selected, the randomness of PUF data is enhanced through mathematical permutations and combinations. Moreover, the strong PUF read operation also utilizes the sense amplifier SA 350 in the bit line decoder 130 of FIG. 1 to sense the current of the aforementioned multiple bit lines to be selected. In this way, it is possible to utilize the current sensing function in the sense amplifier to extract a large quantity of strong PUF data with a single read operation, so it is possible to quickly obtain PUF data and increase the data throughput of PUF data without the need to set up additional comparison circuits.

The memory array is coupled to the memory controller 110. The word line decoder 120, bit line decoder 130, and sub-block selection circuit 160 are all coupled to the memory controller 110. The bit line decoder 130 may include multiple sense amplifiers SA 350. Each sense amplifier SA 350 is respectively coupled to the corresponding bit lines BL1 to BLn to obtain the sensing current of the corresponding bit lines BL1 to BLN (such as currents Ib1 to IbN in FIG. 2), thus extracting strong PUF data. The quantity of bit lines BL1 to BLN in this embodiment may be 16 kB.

The sub-block selection circuit 160 may be a string select line decoder (SSL decoder). The memory controller 110 enables the corresponding string select lines (such as string select lines SSL0 to SSL3) through the sub-block selection circuit 160 to select one memory sub-block from multiple memory sub-blocks to serve as the memory sub-block for extracting strong PUF data. The memory controller 110 implements the extraction method and detailed steps in various embodiments of this disclosure by controlling the memory block 150, word line decoder 120, bit line decoder 130, and sub-block selection circuit 160 in the memory array.

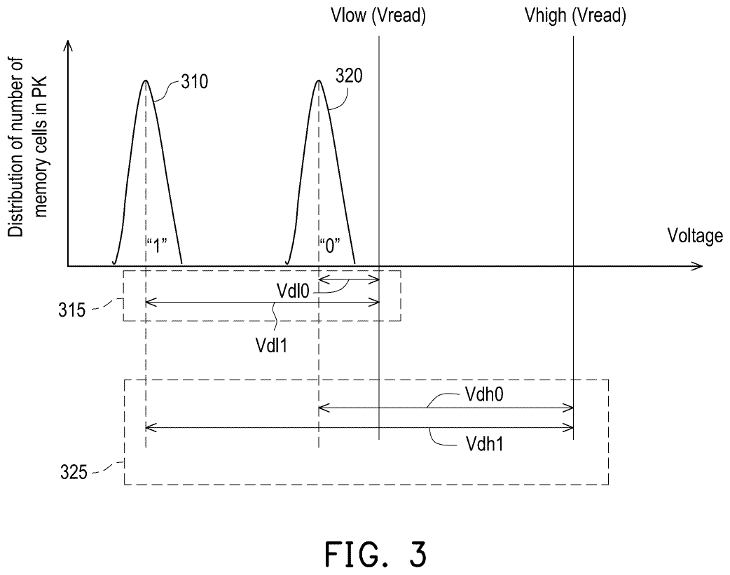

FIG. 3 is a schematic diagram illustrating providing different read voltages to word lines of different pages to change the selection of corresponding pages in a strong PUF read operation according to an embodiment of the disclosure. Referring to both FIG. 2 and FIG. 3, this embodiment will first perform a weak PUF processing operation on the selected memory sub-block (such as memory sub-block Sub_0) in the memory block 150 when extracting PUF data, so that each memory cell in the memory sub-block Sub_0 has PUF data after the weak PUF processing operation is performed. The memory cell distribution 310 and memory cell distribution 320 in FIG. 3 respectively represent the quantity distribution of memory cells in page PK of the memory sub-block Sub_0 that are logic “1” or logic “0”.

When performing a read operation on a specific page (such as page PK), a read voltage Vread is provided to the word line (such as word line WLK) corresponding to this specific page (page PK). Referring to FIG. 3, when the read voltage Vread is the lower first voltage Vlow, as shown in the dash-lined block 315 in FIG. 3, the voltage difference Vd11 between the threshold voltage of memory cells in the memory cell distribution 310 and the first voltage Vlow is greater than the voltage difference Vd10 between the threshold voltage of the memory cells in the memory cell distribution 320 and the first voltage Vlow, and the voltage difference Vd10 is smaller. Therefore, there is a large current value difference between the sensing currents (such as currents Ib1 to IbN in FIG. 2) on the corresponding bit lines when in memory cell distribution 310 or the memory cell distribution 320, making it easy to determine the bit value of a PUF data thereof using the preset current threshold in the sense amplifier SA 350 in FIG. 1. This embodiment refers to the phenomenon in the dash-lined block 315 in FIG. 3 as “low gate overdrive”, and may provide the first voltage Vlow to the word line corresponding to the page to be selected to perform a read operation, thus more clearly presenting the PUF data in the page to be selected.

Conversely, when the read voltage Vread is the higher second voltage Vhigh, as shown in the dash-lined block 325 in FIG. 3, although the voltage difference Vdh1 between the threshold voltage of the memory cells in the memory cell distribution 310 and the first voltage Vlow is still greater than the voltage difference Vdh0 between the threshold voltage of the memory cells in the memory cell distribution 320 and the first voltage Vlow, the value of the voltage difference Vdh0 is greater than the value of the voltage difference Vd10. Therefore, there is a small current value difference between the sensing currents (such as currents Ib1 to IbN in FIG. 2) of the corresponding bit lines when in the memory cell distribution 310 or 320, making it less easy to determine the bit value of a PUF data thereof using the preset current threshold in the sense amplifier SA 350 in FIG. 1. This embodiment refers to the phenomenon as “high gate overdrive”, and may provide the second voltage Vhigh to the word lines corresponding to multiple pages other than the page to be selected to perform a read operation, thereby ignoring the PUF data in the non-page to be selected.

In other words, this embodiment may utilize “high gate overdrive” and “low gate overdrive” in FIG. 3 to select the corresponding first voltage Vlow or second voltage Vhigh, and correspondingly modulate the sensing currents (such as currents Ib1 to IbN in FIG. 2) of the corresponding bit lines, thereby making it easy to distinguish and determine the bit value of a PUF data thereof using the preset current threshold in the sense amplifier SA 350 in FIG. 1. Those who apply this embodiment may appropriately adjust the voltage values of the first voltage Vlow, the second voltage Vhigh, and the preset current threshold according to their needs, thereby controlling the ratio of logic “1”/logic “0” in the PUF data according to the standard of hamming weight of 0.5 in mathematical probability. In this embodiment, the voltage value of the first voltage Vlow is less than the voltage value of the second voltage Vhigh, and the voltage values of both the first voltage Vlow and the second voltage Vhigh are greater than the threshold voltage in the memory cells.

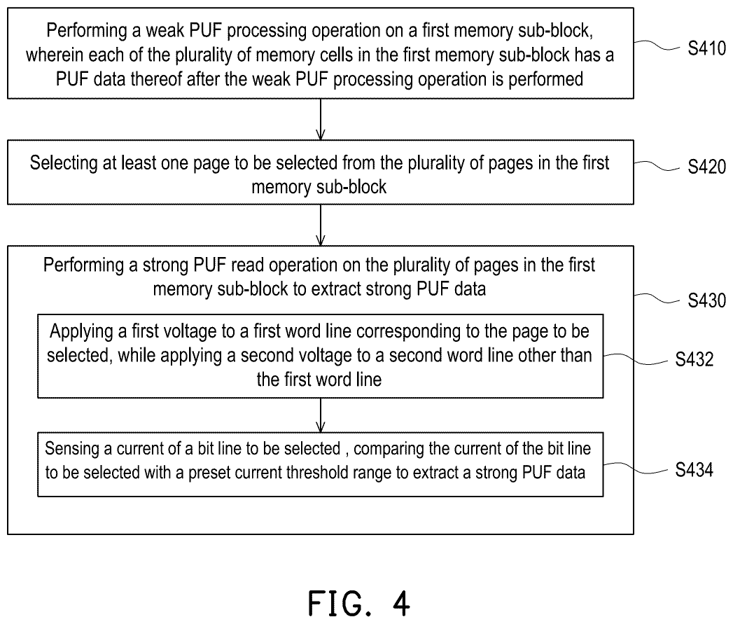

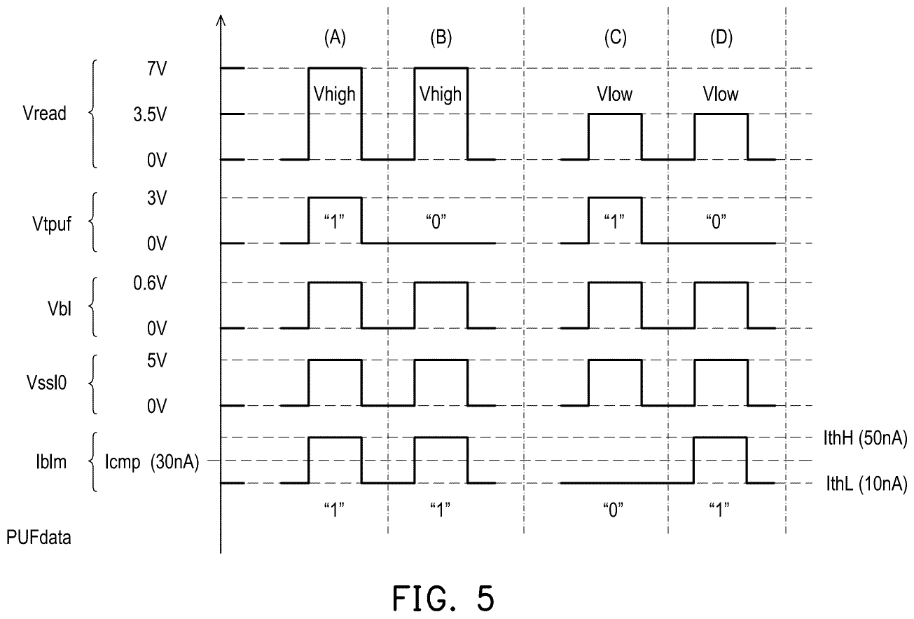

FIG. 4 is a flowchart of an extraction method of a physically unclonable function in a memory device according to an embodiment of the present disclosure. FIG. 5 is a diagram illustrating various signals in an example of the extracting method of FIG. 4. Referring to both FIG. 1 and FIG. 4, in step S410, the memory controller 110 in FIG. 1 controls the sub-block selection circuit 160 to select one of the multiple memory sub-blocks in the memory block 150 as a first memory sub-block Sub_0, and performs a weak PUF processing operation on the first memory sub-block Sub_0. Each memory cell in the first memory sub-block Sub_0 has a PUF data thereof after the weak PUF processing operation is performed.

The weak PUF processing operation in this embodiment may be one of a gate-induced drain leakage (GIDL) erase operation, a programming interference operation, a read interference operation, and a programming delay operation. Those who apply this embodiment may select different PUF processing technologies according to their needs to serve as the weak PUF processing operation of this embodiment, allowing each memory cell in the first memory sub-block Sub_0 to possess random threshold voltages, thereby generating corresponding PUF data. Preferably, the PUF data on each page has independence from one another, thereby complying with the weak PUF processing operation of this embodiment.

In step S420, the memory controller 110 selects at least one page to be selected from multiple pages in the first memory sub-block Sub_0 (such as pages P1 to P96 in FIG. 2). For ease of explanation and to match the example presented in FIG. 5, the page to be selected in this embodiment is page PK. Those who apply this embodiment may select multiple pages as page to be selected according to their needs, for example, selecting 2, 3, 5 or a required number of pages as page to be selected, thereby increasing the randomness of PUF data. Those who apply this embodiment may select the number of these required pages through input commands, or designate some pages as the aforementioned page to be selected.

In step S430, the memory controller 110, through the word line decoder 120 and the bit line decoder 130, performs a strong PUF read operation on multiple pages (such as pages P1 to P96 in FIG. 2) in the first memory sub-block Sub_0 to extract strong PUF data. The strong PUF read operation in step S430 includes a multi-page read operation. The “multi-page read operation” in this embodiment provides different read voltages Vread to each page (pages P1 to P96 in FIG. 2) in the same memory sub-block (such as memory sub-block Sub_0), thereby sensing corresponding sensing currents of the bit lines to be selected among the bit lines BL1 to BLN, thus obtaining strong PUF data.

The detailed of step S430 may include steps S432 and S434. Referring to FIG. 1, FIG. 4, and FIG. 5 simultaneously, in step S432, the memory controller 110 controls the word line decoder 120 to apply a first voltage Vlow to the first word line (such as word line WLK) corresponding to the page to be selected (such as page PK), while applying a second voltage Vhigh to the second word lines (such as word lines WL1 to WLK−1, WLK+1 to WL96) other than the first word line (such as word line WLK). The second word line is multiple word lines other than the first word line (word line WLK). The first voltage Vlow is different from the second voltage Vhigh, and the voltage value of the first voltage Vlow is less than the voltage value of the second voltage Vhigh. In other words, the word line decoder 120 in this embodiment is controlled by the memory controller 110, thereby selectively applying the first voltage Vlow or the second voltage Vhigh to word lines corresponding to different pages.

In step S434, after applying the first voltage Vlow to the first word line and applying the second voltage Vhigh to the second word line other than the first word line, the memory controller 110 controls the bit line decoder 130 to sense the currents of the multiple bit lines to be selected, and compare the currents (e.g., current Ibm) of the bit lines to be selected with a preset current threshold (such as the range between sensing currents IthH and IthL and a preset current threshold Icmp in FIG. 5) to extract strong PUF data. The bit lines to be selected are selected from multiple bit lines BL1 to BLN of the first memory sub-block Sub_0.

The signal waveforms (A) and (B) in FIG. 5 indicate that the word line decoder 120 provides the second voltage Vhigh as the read voltage Vread of the second word line on the second word line corresponding to pages P1 to PK−1 and PK+1 to P96 other than the page to be selected PK in the first memory sub-block Sub_0. Moreover, in the signal waveforms (A) and (B) in FIG. 5, the bit line decoder 130 provides an enable pulse of about 0.6V for the voltage Vb1 on the bit line BLm, and the sub-block selection circuit 160 provides a voltage Vss10 of about 5V on the string select line SSL0 corresponding to the first memory sub-block Sub_0. In FIG. 5, the second voltage Vhigh is exemplified as 7V.

Although the threshold voltage Vtpuf in the memory cell MC after the weak PUF processing operation represents logic “1” (corresponding to signal waveform (A)) or logic “0” (corresponding to signal waveform (B)), due to the “high gate overdrive” in FIG. 3, the signal waveform (B) corresponds to a large voltage difference Vdh1 in the dash-lined block 325 in FIG. 3, the sensing current of the bit line BL corresponding to this signal waveform (B) will larger than the current threshold Icmp; the signal waveform (A) corresponds to the voltage difference Vdh0 in the dash-lined block 325 in FIG. 3, which is smaller than the voltage difference Vdh1, but the sensing current of the bit line BL corresponding to this signal waveform (A) will still be greater than the current threshold Icmp in FIG. 5. In this embodiment, the current threshold Icmp is, for example, 30 nA, and the sensing current IthH on the bit line BL corresponding to the signal waveforms (A) and (B) is, for example, approximately 50 nA. As a result, the PUF data PUFdata after being subjected to the strong PUF read operation by providing the second voltage Vhigh to the word lines are all logic “1”, so the PUF data in the non-page to be selected is ignored.

The signal waveforms (C) and (D) in FIG. 5 indicate that the word line decoder 120 provides the first voltage Vlow as the read voltage Vread of the first word line on the first word line (e.g., word line WLK) corresponding to the page to be selected PK in the first memory sub-block Sub_0. Due to the “low gate overdrive” in FIG. 3, the signal waveform (D) corresponds to a large voltage difference Vdh1 in the dash-lined block 315 in FIG. 3, the sensing current of the bit line BL corresponding to this signal waveform (D) will larger than the current threshold Icmp; the signal waveform (C) corresponds to the smallest voltage difference Vdh0 in the dash-lined block 325 in FIG. 3, therefore the sensing current of the bit line BL corresponding to this signal waveform (C) will be less than the current threshold Icmp in FIG. 5. In this embodiment, the sensing current IthL on the bit line BL corresponding to the signal waveform (C) is approximately 10 nA, and the sensing current IthH on the bit line BL corresponding to the signal waveform (D) is approximately 50 nA. As a result, the PUF data PUFdata after being subjected to the strong PUF read operation by providing the first voltage Vlow to the word lines will be categorized into logic “1” (corresponding to signal waveform (D)) or logic “0” (corresponding to signal waveform (C)), thereby obtaining the PUF data in the page to be selected (e.g., page PK).

In the multi-page read operation in FIG. 5, only page PK is selected to perform the strong PUF read operation, while other pages P1 to PK−1 and PK+1 to P96 are not selected, so as to simplify this embodiment. Those who apply this embodiment may select multiple pages as the aforementioned page to be selected, and because the number of pages to be selected increases, the permutations and combinations of threshold voltages Vtpuf in each memory cell on each memory cell string also correspondingly increase, rather than just the four modes in FIG. 5. Therefore, those who apply this embodiment need to adaptively set the preset current threshold range according to the number of pages to be selected based on the standard of Hamming weight of 0.5 in mathematical probability, that is, to adjust the values of the current threshold Icmp.

This embodiment may, in the aforementioned multi-page read operation, select one or more pages and select some of the bit lines from bit lines BL1 to BLN as multiple bit lines to be selected, thereby enhancing the randomness of PUF data through mathematical permutations and combinations. For example, assuming X pages are selected from pages P1 to P96 of the memory sub-block Sub_0, and Y bit lines are selected from bit lines BL1 to BLN as bit lines to be selected for performing the aforementioned strong PUF read operation. That is to say, theoretically, based on the memory sub-block Sub_0, the strong PUF read operation may possess a result that is the product of the permutations and combinations of selecting L pages from 96 pages multiplied by the permutations and combinations of selecting Y bit lines from N bit lines.

The number of bit lines N in this embodiment may be 16 kB. The number of bits of the strong PUF data equals the number of bit lines to be selected, that is to say, the number of bits of the strong PUF data will be less than or equal to 16 kB.

In the actual implementation of this extraction method, in order to better compare the sensing currents of the bit lines to be selected with the preset current threshold range to enhance the distinction of strong PUF data, the embodiment of the present disclosure will filter out some of the aforementioned permutations and combinations, so as to effectively distinguish the strong PUF data.

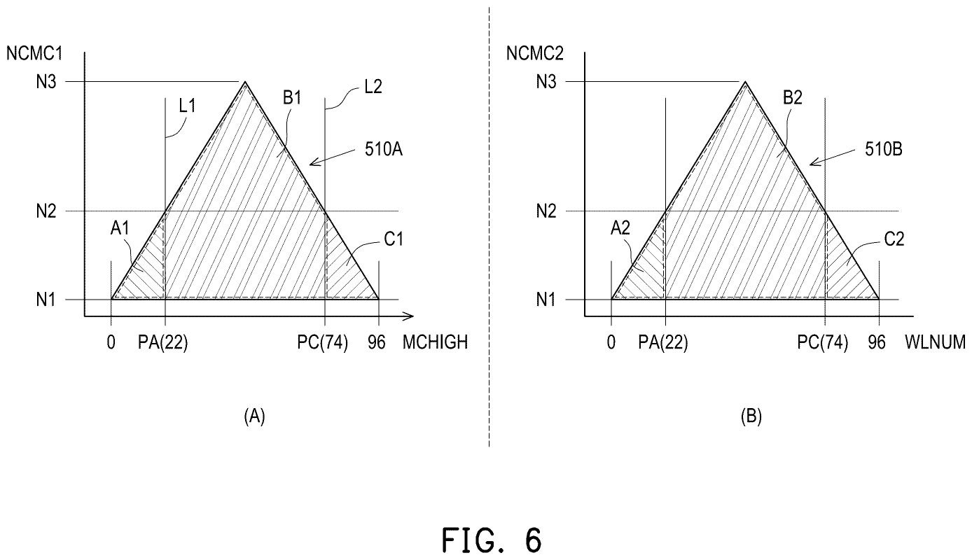

FIG. 6 is a natural probability distribution diagram of the number of memory cells with high threshold voltage on a specific memory cell string (e.g., memory cell string 121 in FIG. 2) in pages P1 to P96 of the memory sub-block Sub_0. Assuming that the memory cell string 121 in FIG. 2 includes 96 memory cells, with each memory cell being allocated to different pages P1 to P96.

In part (A) of FIG. 6, the horizontal axis of illustration diagram 510A represents the number of memory cells MCHIGH with high threshold voltage among the 96 memory cells on the memory cell string 121 in FIG. 2, and the vertical axis of illustration diagram 510A represents the number of permutations and combinations NCMC1 of the 96 memory cells. The value N1 is the number of permutations and combinations where all 96 memory cells are memory cells with high threshold voltage, as shown in equation (1).

$$N 1 = {C}_{0}^{96} , {C}_{96}^{96} \qquad ( 1 )$$

The value N3 is the number of permutations and combinations where half of the 96 memory cells have high threshold voltage and the other half have low threshold voltage, as shown in equation (2).

$$N 3 = {C}_{48}^{96} , {C}_{48}^{96} \qquad ( 2 )$$

Through experimental simulation, this embodiment establishes line segments L1 and L2, where line segment L1 corresponds to a value PA (e.g., value “22”), and line segment L2 corresponds to a value PA (e.g., value “74”). The value “PA(22)” represents possessing 22 memory cells with high threshold voltage. The value “PC(74)” represents possessing 74 memory cells with high threshold voltage.

The value N2 is the number of permutations and combinations where 22 of the 96 memory cells have high threshold voltage/low threshold voltage and the other half have low threshold voltage/high threshold voltage, as shown in equation (3).

$$N 2 = {C}_{22}^{96} , {C}_{74}^{96} \qquad ( 3 )$$

Illustration diagram 510A is divided into blocks A1, B1, and C1 by line segments L1 and L2. Blocks A1 and C1 are the permutations and combinations required by this embodiment. In the permutations and combinations in blocks A1 and C1, the corresponding currents are more easily distinguished as logic “1” or logic “0” to extract strong PUF data. Block B1 represents permutations and combinations that need to be filtered out and not executed.

In part (B) of FIG. 6, the horizontal axis of illustration diagram 510B represents the number of word lines WLNUM among word lines WL1 to WL96 in FIG. 2 that provide the first voltage Vlow, and the vertical axis of illustration diagram 510B represents the number of permutations and combinations NCMC2 of the 96 memory cells. Similar to part (A) of FIG. 6, illustration diagram 510B is also divided into blocks A2, B2, and C2 by line segments L1 and L2. Blocks A2 and C2 are the permutations and combinations required by this embodiment. In the permutations and combinations in blocks A2 and C2, the corresponding currents are more easily distinguished as logic “1” or logic “0” to extract strong PUF data. Block B2 represents permutations and combinations that need to be filtered out and not executed.

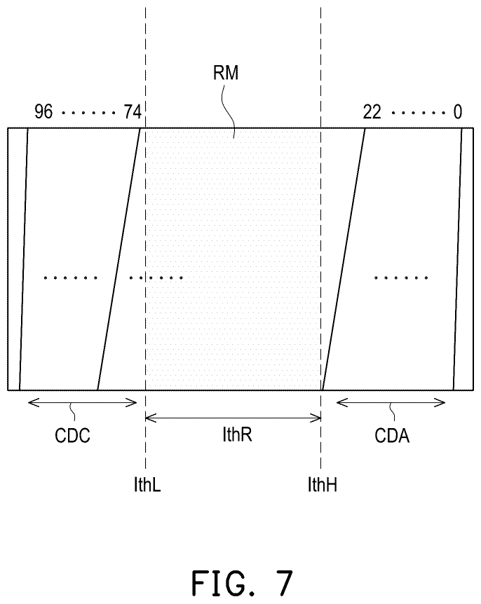

FIG. 7 is a diagram of the current threshold range between sensing currents IthL and IthH in FIG. 6. FIG. 7 presents the current distributions corresponding to areas A1/A2, B1/B2, and C1/C2 respectively, where current distribution CDC is the low current range of the area C1/C2, current distribution DCA is the high current range of the area A1/A2, and the area RM represents the read margin. The area RM is used to represent the preset current threshold range IthR between the sensing currents IthH and IthL.

Those applying this embodiment may adjust the values PA and PC corresponding to line segments L1 and L2 according to their requirements. For example, the value PA may be adjusted to correspond to the value “16”, and the value PC may be adjusted to correspond to the value “80” as needed.

According to FIG. 6 and FIG. 7, the quantity of strong PUF data TCRP that can be provided by this embodiment may be presented through equation (4), where M is the total number of middle pages in the memory sub-block, N is greater than or equal to 0 and less than or equal to M, the number of bit lines is 16 kB, and the number of bit lines to be selected is 64.

$$TCRP = {\sum }_{N = 0}^{M} [ ( {C}_{0}^{N} + … + {C}_{PA}^{N} ) + ( {C}_{PC}^{N} + … + {C}_{N}^{N} ) ] \times {C}_{64}^{16 kB} \times {C}_{N}^{M} \qquad ( 4 )$$

To sum up, the embodiments of the present disclosure primarily utilize the existing hardware structure of memory devices (such as bit line decoders, word line decoders, sub-block selection circuits, etc.) and some additional functionalities (such as corresponding functions added to the memory controller and multi-page read operations) to achieve PUF data extraction. In the aforementioned multi-page read operation of the present embodiment, one or more pages are selected, and some of bit lines are selected from BL1 to BLN as multiple bit lines to be selected, thereby enhancing the randomness of PUF data through mathematical permutations and combinations. Furthermore, by utilizing sense amplifiers in the bit line decoder to sense currents of the multiple bit lines to be selected, a substantial quantity of strong PUF data may be extracted in a single read operation, increasing PUF data throughput without requiring additional comparison circuits.

What is claimed is:

1. An extraction method of a physically unclonable function (PUF) in a memory device, wherein the memory device comprises a memory block, wherein the memory block comprises a plurality of memory sub-blocks, each of the plurality of the memory sub-blocks comprises a plurality of memory cells, the plurality of the memory cells are divided into a plurality of pages, and the plurality of the pages correspond to a plurality of word lines,
the extraction method comprising:
performing a weak PUF processing operation on a first memory sub-block among the plurality of the memory sub-blocks, wherein each of the plurality of the memory cells in the first memory sub-block has a PUF data thereof after the weak PUF processing operation is performed;
selecting at least one page to be selected from the plurality of the pages in the first memory sub-block; and
performing a strong PUF read operation on the plurality of the pages in the first memory sub-block to extract strong PUF data,
wherein the step of performing the strong PUF read operation on the plurality of the pages in the first memory sub-block comprises:
applying a first voltage to a first word line corresponding to the at least one page to be selected, while applying a second voltage to a second word line other than the first word line, wherein the second word line is the plurality of the word lines other than the first word line, and the first voltage is different from the second voltage; and
after applying the first voltage to the first word line and applying the second voltage to the word lines other than the first word line, sensing currents of a plurality of bit lines to be selected to extract the strong PUF data, wherein the plurality of the bit lines to be selected is selected from a plurality of bit lines of the first memory sub-block.

2. The extraction method according to claim 1, wherein the step of sensing the currents of the bit lines to be selected to extract the strong PUF data comprises:
comparing the currents of the bit lines to be selected with a preset current threshold to extract the strong PUF data.

3. The extraction method according to claim 2, further comprising:
setting the preset current threshold based on a number of the at least one page to be selected.

4. The extraction method according to claim 1, wherein a value of the first voltage is less than a value of the second voltage.

5. The extraction method according to claim 1, wherein a number of bits of the strong PUF data is less than or equal to a number of the plurality of the bit lines of the first memory sub-block.

6. The extraction method according to claim 5, wherein the number of the plurality of the bit lines of the first memory sub-block is 16 kB, and the number of the bits of the strong PUF data is less than or equal to 16 kB.

7. The extraction method according to claim 1, wherein the weak PUF processing operation is one of a gate-induced drain leakage (GIDL) erase operation, a programming interference operation, a read interference operation, and a programming delay operation.

8. A memory device, comprising:
a memory array, comprising a memory block, wherein the memory block comprises a plurality of memory sub-blocks, each of the plurality of the memory sub-blocks comprises a plurality of memory cells, the plurality of the memory cells are divided into a plurality of pages, and the plurality of the pages correspond to a plurality of word lines;
a memory controller, coupled to the memory array;
a bit line decoder, coupled to the memory controller; and
a word line decoder, coupled to the memory controller,
wherein the memory controller is configured to:
perform a weak PUF processing operation on a first memory sub-block among the plurality of the memory sub-blocks, wherein each of the plurality of the memory cells in the first memory sub-block has a PUF data thereof after the weak PUF processing operation is performed;
select at least one page to be selected from the plurality of the pages in the first memory sub-block; and
through the word line decoder and the bit line decoder, perform a strong PUF read operation on the plurality of the pages in the first memory sub-block to extract strong PUF data,
wherein the memory controller controls the word line decoder to apply a first voltage to a first word line corresponding to the at least one page to be selected, while applying a second voltage to a second word line other than the first word line, wherein the second word line is the plurality of the word lines other than the first word line, and the first voltage is different from the second voltage.

9. The memory device according to claim 8, wherein the memory controller controls the bit line decoder to:
after applying the first voltage to the first word line and applying the second voltage to the word lines other than the first word line, sense currents of a plurality of bit lines to be selected to extract the strong PUF data, wherein the plurality of the bit lines to be selected is selected from a plurality of bit lines of the first memory sub-block; and
compare the currents of the bit lines to be selected with a preset current threshold to extract the strong PUF data.

10. The memory device according to claim 9, wherein the memory controller sets the preset current threshold based on a number of the at least one page to be selected.

11. The memory device according to claim 8, wherein a value of the first voltage is less than a value of the second voltage.

12. The memory device according to claim 9, wherein a number of bits of the strong PUF data is less than or equal to a number of the plurality of the bit lines of the first memory sub-block.

13. The memory device according to claim 12, wherein the number of the plurality of the bit lines of the first memory sub-block is 16 kB, and the number of the bits of the strong PUF data is less than or equal to 16 kB.

14. The memory device according to claim 8, wherein the weak PUF processing operation is one of a gate-induced drain leakage (GIDL) erase operation, a programming interference operation, a read interference operation, and a programming delay operation.

15. The memory device according to claim 8, further comprising:
a sub-block selection circuit, coupled to the memory controller,
wherein the memory controller controls the sub-block selection circuit to select the first memory sub-block from the plurality of the memory sub-blocks.
